(19) United States
(12) Patent Application Publication
(10) Pub. No.: US 2005/0085059 A1
(43) Pub. Date: Apr. 21, 2005

(54) Method for manufacturing word line of semiconductor device

(75) Inventors: Jae Soo Kim, Gyeonggi-do (KR); Su Ho Kim, Gyeonggi-do (KR); Yong Seok Eun, Gyeonggi-do (KR)

Correspondence Address: HELLER EHRMAN WHITE & MCAULIFFE LLP, 1666 K STREET,NW, SUITE 300, WASHINGTON, DC, 20006, US

(73) Assignee: Hynix Semiconductor Inc., Gyeonggi-do (KR)

(21) Appl. No.: 10/879,150

(22) Filed: Jun. 30, 2004

(30) Foreign Application Priority Data
Oct. 17, 2003 (KR) 2003-0072587

(51) Int. Cl. H01L 21/8242; H01L 21/3205; H01L 21/4763; H01L 29/76; H01L 29/94; H01L 31/062; H01L 31/113; H01L 31/119

(52) U.S. Cl. 438/592; 257/413

(57) ABSTRACT

The present invention relates to a method for forming a word line wherein a gate electrode comprises aluminum silicide (AlSiₓ) having low electrical resistance and stress to form a word line having low specific resistance, thereby increasing processing speed of a device and repressing micro-crack and lifting effects by stress alleviation between films to prevent fail of a device.

### BACKGROUND OF THE INVENTION

1. Field of the Invention

The present invention generally relates to a method for manufacturing a word line of a semiconductor device, and more specifically, to a method for forming a word line wherein a gate electrode is formed using aluminum silicide (AlSiₓ) having low electrical resistance and stress to form a word line having low specific resistance, thereby increasing processing speed of a device and inhibiting micro-crack and lifting effects by alleviated stress between films to prevent fail of a device.

2. Description of the Prior Art

For high integration of a semiconductor device, as the size of the device becomes smaller, the size of a cell for reading/writing an electric signal in a device also decreases. However, while the power consumption of the device increases due to the reduction of the cell increases, the sheet resistance of a gate electrode included in a word line increases, thereby reducing the processing speed of the device.

Generally, materials for forming a gate electrode are required to have low sheet resistance, processability, easy etching property for forming a pattern, durable oxidative, good adsorptivity, mechanical stability such as low stress and smoothness of the surface in formation of a film. Instead of conventional poly silicon, a metal has been widely used as a material which satisfies the above conditions.

However, since the metal is formed by a high thermal process, a metal is melt in a process for forming a gate electrode. Otherwise, a lower insulating film, for example, a metal silicide film which does not regulate formation between a polysilicon and an interface is irregularly formed.

In order to solve the problem, an electrode formation process using metal silicide (MSiₓ) having a polyside structure which is uniformly formed on an insulating film due to higher adhesion property with a polysilicon film than metal has been developed. The metal silicide satisfies the above-described conditions and is stable even though it is formed at a higher temperature than the metal.

Currently, tungsten silicide (WSiₓ) has been widely used as a metal silicide electrode material in a general word line structure (see FIG. 1).

FIGS. 2a to 2c are diagrams illustrating a method for manufacturing a word line comprising a conventional tungsten silicide electrode.

Referring to FIG. 2a, a gate oxide film (SiO₂) 3 is formed on a silicon substrate 1.

As shown in FIG. 2b, a doped polysilicon film 5 and a tungsten silicide film for gate electrode 7, and a hard mask insulating nitride film 9 are sequentially formed on the gate oxide film 3 of FIG. 2a.

The tungsten silicide film is formed at a thickness ranging from 800 to 1200 Å at 430° C., and has sheet resistance ranging from 90 to 102 Ω/□.

As shown in FIG. 2c, an etching process is performed on the resulting structure of FIG. 2b using a mask to form a word line 10 having a sequentially stacked structure of a gate oxide film pattern 3a, a polysilicon film pattern 5a, a tungsten suicide pattern 7a and a hard mask insulating film pattern 9a.

Here, the etching process has different conditions in each layer. For example, the etching process for forming the tungsten silicide pattern is performed at a pressure ranging from 50 to 75 mT and at a power ranging from 600 to 800W using etching gases consisting of CF₄ of 5˜100 sccm, CHF₃ of 25˜40 sccm, O₂ of 7˜19 sccm and Ar of 70˜150 sccm.

However, the word line including a tungsten silicide electrode manufactured by the above-described method has increased sheet resistance as a semiconductor device becomes gradually integrated. Also, it is impossible to secure a predetermined processing speed required in a device operation, and non-resistance of the word line increases due to increase of sheet resistance. As a result, stress between films increases, and leakage current are formed by generated micro-crack and lifting.

### SUMMARY OF THE INVNETION

Accordingly, it is an object of the present invention to provide a method for forming a word line of a semiconductor device, wherein a gate electrode comprises a material having low sheet resistance to reduce the size of the semiconductor device and to increase the processing speed of the device.

In an embodiment, there is provided a method for manufacturing a word line of a semiconductor device including a gate electrode comprising aluminum silicide.

In an embodiment, a word line of a semiconductor device comprises a gate insulating film, a gate electrode and a hard mask nitride film. Here, the gate electrode comprises an aluminum silicide film.

A disclosed method for manufacturing a word line of a semiconductor device, comprising the steps of:
forming a gate oxide film on a semiconductor substrate;
forming a polysilicon film on the gate oxide film;
forming an aluminum silicide (AlSiₓ) film for gate electrode on the polysilicon film;
forming a hard mask nitride film on the aluminum silicide film; and
selectively etching the hard mask nitride film, the aluminum silicide film for gate electrode, the polysilicon film and the gate oxide film to form a word line.

Preferably, the step of forming aluminum silicide film is performed at a temperature ranging from 400 to 1414° C. at an aluminum to silicon ratio ranging from 98.5˜1 atom % to 1.5˜99 atom %, preferably 87.8 atom % to 12.2 atom %.

The optimum composition ratio of aluminum and silicon can be obtained with reference to FIG. 3. That is, when the content of silicon is less than 1.5, the gate electrode film comprises aluminum. When the composition ratio of aluminum and silicon is applied as an 87.8 atom %:12.2 atom % at a eutectic point of 577° C., two materials are completely mixed each other at a liquid state.

### BRIEF DESCRIPTION OF THE DRAWINGS

FIG. 1 is a cross-sectional diagram illustrating a conventional word line electrode comprising a tungsten silicide electrode.

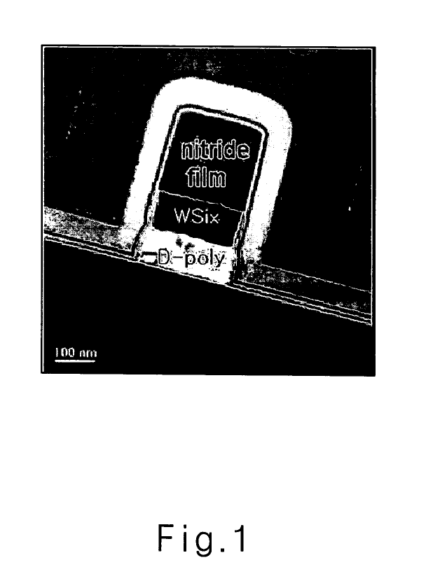

FIGS. 2a to 2c are diagrams illustrating a method for manufacturing a word line comprising a conventional tungsten silicide electrode.

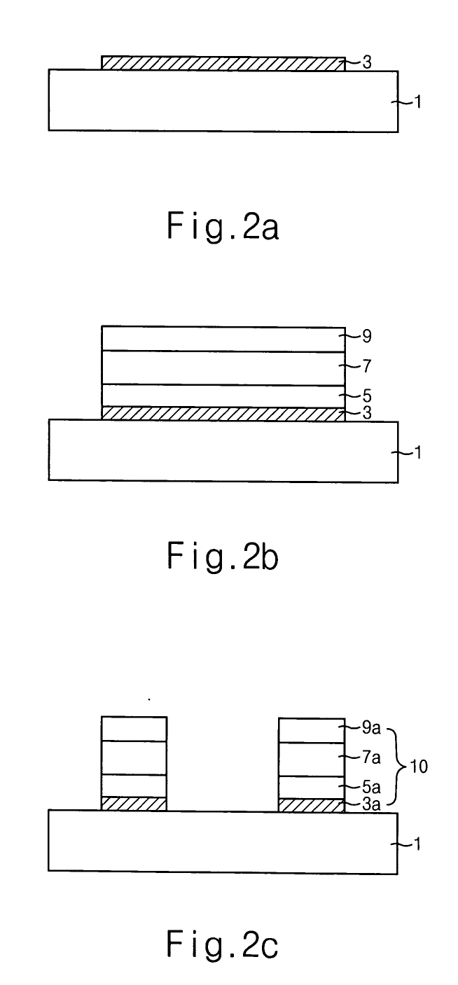

FIG. 3 is a graph illustrating a eutectic point of Al and Si.

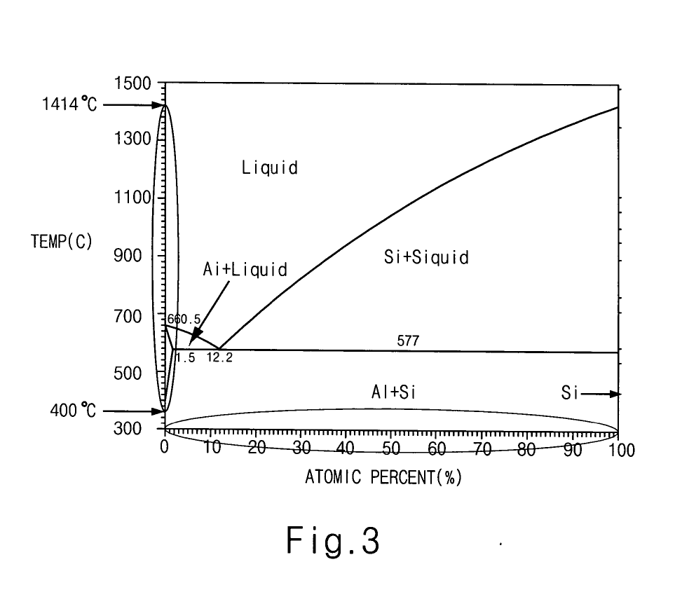

FIGS. 4a to 4c are diagrams illustrating a method for manufacturing a word line comprising an aluminum silicide electrode according to an embodiment of the present invention.

### DETAILED DESCRIPTION OF THE PREFERRED EMBODIMENTS

The present invention will be described in detail with reference to the accompanying drawings.

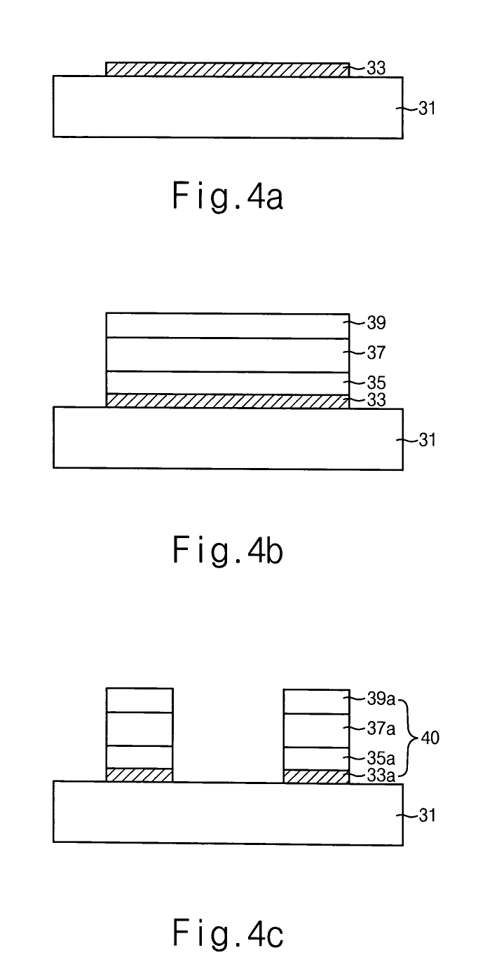

Referring to FIG. 4a, a gate oxide film 33 which is a gate insulating film is formed on a silicon substrate 31. Here, a thickness of the gate oxide film ranges from 52 to 56 Å.

As shown in FIG. 4b, a doped polysilicon film 35 is formed on the gate oxide film 33 of FIG. 4a, and an aluminum silicide film for gate electrode 37 is formed on the doped polysilicon film 35. Here, a thickness of the polysilicon film 35 ranges from 785 to 875 Å.

The aluminum silicide film 37 is formed at a temperature ranging from 400 to 1414° C. at an aluminum to silicon ratio ranging from 98.5˜1 atom % to 1.5˜99 atom %. Here, a thickness of the aluminum silicide film ranges from 800 to 1020 Å, preferably from 980 to 1020 Å.

Here, the aluminum silicide film 37 improves performance of a gate electrode due to general characteristics of the gate electrode material. For example, the gate electrode material is stable in a thermal process at high temperature, and has easy etching property for pattern formation, anti-oxidation and mechanical stability.

In addition, the gate electrode comprised aluminum silicide having low resistance and stress forms a low surface resistance value in a word line, thereby increasing the processing speed of the device.

For example, when a gate electrode comprises aluminum silicide film 37 mixed at an aluminum to silicon ratio ranging from 45.5 atom % to 54.5 atom %, the gate electrode has a non-resistance value of about 3μΩ·cm.

Therefore, if the gate electrode comprises an aluminum silicide material having a lower surface resistance value than a conventional tungsten silicide electrode having a surface resistance value of 90˜102 Ω/□, a word line having a low non-resistance value can be formed.

In case of the above-described word line having a low non-resistance value, the stress between films is alleviated, and micro-crack and lifting effect of the device are inhibited, thereby preventing mis-operation of the device and leakage current and providing a device of high concentration.

Then, a hard mask nitride film 39 is formed on the aluminum silicide film 37 at a thickness ranging from 1880 to 2220 Å.

Referring to FIG. 4c, a photo-etching process is performed using a word line mask (not shown) to form a word line 40 having a stacked structure of a gate oxide film pattern 33a, a doped polysilicon film pattern 35a, an aluminum silicide pattern 37a and a hard mask insulating film pattern 39a.

Here, the word line according to an embodiment of the present invention can be applied to all kinds of devices which use a metal gate of DRAM. In addition, a method for forming the word line according to an embodiment of the present invention can be applied to a word line formation process of flash EEPROM (electrically erasable PROM) and SRAM.

As discussed earlier, since a gate electrode comprising an aluminum silicide according to an embodiment of the present invention includes general characteristics of gate electrode materials, a gate electrode is easily formed. Furthermore, the gate electrode has low surface resistance and stress, thereby increasing the processing speed of a device. Additionally, the low surface resistance value obtained from the above-described method forms a low non-resistance value in a word line. As a result, the stress between films is alleviated, and micro-crack and lifting effect are inhibited, thereby preventing mis-operation of the device and leakage current.

1. A word line of a semiconductor device, comprising a gate insulating film, a gate electrode and a hard mask nitride film, wherein the gate electrode comprises an aluminum silicide film.

2. A method for manufacturing a word line of a semiconductor device, comprising the steps of:
forming a gate oxide film on a semiconductor substrate;
forming a polysilicon film on the gate oxide film;
forming an aluminum silicide (AlSiₓ) film for gate electrode on the polysilicon film;
forming a hard mask nitride film on the aluminum silicide film; and
selectively etching the hard mask nitride film, the aluminum silicide film for gate electrode, the polysilicon film and the gate oxide film to form a word line.

3. The method according to claim 2, wherein the step of forming the aluminum silicide film is performed at a temperature ranging from 400 to 1414° C. at an aluminum to silicon ratio ranging from 98.5˜1 atom % to 1.5˜99% atom %.

4. The method according to claim 2, wherein a thickness of the aluminum silicide film ranges from 800 to 1020 Å.

5. The method according to claim 2, wherein a thickness of the aluminum suicide film ranges from 980 to 1020 Å.
